(19) United States
(12) Patent Application Publication
(10) Pub. No.: US 2026/0016515 A1
(43) Pub. Date: Jan. 15, 2026

(54) SYNCHRONOUS PHASE ELECTRIC METER MEASURING SYSTEM

(71) Applicant: Aclara Technologies LLC, St. Louis, MO (US)

(72) Inventors: Roger Alan Smith, Gibsonia, PA (US); Rebecca Ross, Apollo, PA (US)

(21) Appl. No.: 19/268,386

(22) Filed: Jul. 14, 2025

Related U.S. Application Data
(60) Provisional application No. 63/671,622, filed on Jul. 15, 2024.

(51) Int. Cl. G01R 22/06; G01R 23/00

(52) U.S. Cl. CPC G01R 22/063; G01R 23/005

(57) ABSTRACT

A processor of an electric meter receives a measurement signal corresponding to an input electricity, initiates a first counter at a first edge of a first pulse-per-second (PPS) signal of an RF communications system, and stops the first counter at a first edge of the measurement signal. The processor determines a first counter value from the first counter and initiates a second counter at a first edge of a second PPS signal of the RF communications system. The processor stops the second counter at a second edge of the measurement signal. The processor also determines a second counter value from the second counter, determines an actual sampling frequency of the measurement signal, and compares the actual sampling frequency of the measurement signal to a predetermined sampling frequency. The controller also performs a mitigation action in response to determining that the actual sampling frequency differs from the predetermined sampling frequency.

### CROSS REFERENCE TO RELATED APPLICATIONS

The present application claims priority to U.S. Provisional Patent Application No. 63/671,622 filed on Jul. 15, 2024, entitled “Synchronous Phase Electric Meter Measuring System.” The entire contents of the provisional application are incorporated herein in their entirety by reference.

### FIELD

Embodiments relate to electric utility meters.

### SUMMARY

Facilities (for example, homes, businesses, etc.) receive electricity from distributions transformers. The distribution transformers transform high voltages received from power lines to voltages suitable for residential and commercial use (for example, 120 Volts (V) and/or 240 V). Electric meters may be installed at facilities to collect data regarding the incoming electricity. The electric meters are electrically coupled to the facility via an electrical socket and collect data regarding the incoming electricity.

Such electric meters may include, among other things, one or more phasor measurement units (PMUs) configured to measure a magnitude and phase angle of an electrical phasor quantity (such as voltage or current) in the electricity grid. Such systems may also be configured to determine frequency and the rate of change of frequency. Time-stamped, digitized voltage and current signals may be provided to a centralized computing system (for example, a centralized server) where they are collated with other time-synchronized signals from other parts of the electric network. The mathematics for power flow analysis (and other analytics) may then be performed on the signal collection as if all the signals were collected by a single instrument.

Many of the computations and analytic analyses involve only the amplitude and relative phase angles of the fundamental sinusoids of each signal. In other words, they may require only the phasors measured synchronously (known as “synchrophasors”). Some methods for computing power flow from phasors have been adapted with respect to asynchronous measurements. However, these methods, which use only phasor magnitudes, are limited in as methods that use both phasor magnitude and angle. In other words, such methods require additional information about the particular network (for example, branch impedances). The ability to measure phase, therefore, creates more opportunities for network analysis.

While PMUs may be utilized on electrical transmission networks, they may not typically be utilized on electrical distribution networks due to cost, as the bandwidth cost of PMUs may be expensive and difficult to employ on the scale necessary for an electrical distribution network.

Furthermore, such measurements require that each device samples measurements of the line voltage at the same sampling frequency/point in time. Clock oscillators are subject to degradation over time (for example, due to environmental and/or aging factors), which may result in changes in the expected produced clock frequencies. Most common solutions to alleviate such degradation involve additional hardware (for example, to control the sampling frequency of the measurement signal), which may increase costs. Again, such costs may not be feasible to employ on a scale necessary for an electrical distribution network.

Thus, the systems and methods described herein provide for an electric utility meter with PMU functionality. More specifically, the systems and methods herein provide for detection and mitigation of changes of a sampling frequency of an electrical distribution system.

One embodiment herein provides an electric utility meter. The electric utility meter includes an input configured to receive input electricity from an electricity source, a radio frequency (RF) communications system, and a controller. The controller includes an electronic processor configured to receive a measurement signal corresponding to the input electricity, initiate, at a first edge of a first pulse-per-second (PPS) signal of the RF communications system, a first counter, and stop, at a first edge of a first sample of the measurement signal, the first counter. The electronic processor is further configured to determine, following stopping the first counter, a first counter value from the first counter, initiate, at a first edge of a second PPS signal of the RF communications system, a second counter, and stop, at a first edge of a second sample of the measurement signal, the second counter. The electronic processor is further configured to determine, following stopping the second counter, a second counter value from the second counter, determine, from the first counter value and the second counter value, an actual sampling frequency of the measurement signal, compare the actual sampling frequency of the measurement signal to a predetermined sampling frequency, and perform a mitigation action in response to determining that the actual sampling frequency differs from the predetermined sampling frequency.

Another embodiment provides an electrical distribution system including an electric utility meter. The electric utility meter including an input configured to receive input electricity from an electricity source, a RF communications system, and a controller. The controller includes an electronic processor configured to receive a measurement signal corresponding to the input electricity, initiate, at a first edge of a first PPS signal of the RF communications system, a first counter, and stop, at a first edge of a first sample of the measurement signal, the first counter. The electronic processor is further configured to determine, following stopping the first counter, a first counter value from the first counter, initiate, at a first edge of a second PPS signal of the RF communications system, a second counter, and stop, at a first edge of a second sample of the measurement signal, the second counter. The electronic processor is further configured to determine, following stopping the second counter, a second counter value from the second counter, determine, from the first counter value and the second counter value, an actual sampling frequency of the measurement signal, compare the actual sampling frequency of the measurement signal to a predetermined sampling frequency, and perform a mitigation action in response to determining that the actual sampling frequency differs from the predetermined sampling frequency.

Yet another embodiment provides a method of operating an electric utility meter. The method includes receiving, at an input of the electric utility meter, a measurement signal corresponding to an input electricity from an electrical source, initiating, at a first edge of a first PPS signal of an RF communications system, a first counter, and stopping, at a first edge of a first sample of the measurement signal, the first counter. The method further includes determining, following stopping the first counter, a first counter value from the first counter, initiating, at a first edge of a second PPS signal of the RF communications system, a second counter, stopping, at a first edge of a second sample of the measurement signal, the second counter, determining, following stopping the second counter, a second counter value from the second counter, and determining, from the first counter value and the second counter value, an actual sampling frequency of the measurement signal. The method further includes comparing the actual sampling frequency of the measurement signal to a predetermined sampling frequency and performing a mitigation action in response to determining that the actual sampling frequency differs from the predetermined sampling frequency.

Other aspects of the disclosure will become apparent by consideration of the detailed description and accompanying drawings.

### BRIEF DESCRIPTION OF THE DRAWINGS

FIG. 1 is a perspective view illustrating an electric according to some embodiments.

FIG. 2 is a block diagram illustrating the electric meter of FIG. 1 according to some embodiments.

FIG. 3 is a schematic circuit diagram of an electrical system including the electric meter of FIG. 1 according to some embodiments.

FIG. 4 is a flowchart illustrating a method of determining and mediating a change in a sampling frequency of the electric meter of FIG. 1 according to some embodiments.

FIG. 5 is a signal over time diagram of a measurement signal and a PPS signal according to some embodiments.

FIG. 6 is a diagram of a frame structure of a measurement signal stored by the electric meter of FIG. 1 according to some embodiments.

FIG. 7 is an electrical distribution network including a plurality of electric meters according to some embodiments.

FIG. 8 is a diagram illustrating a voltage measurements from a plurality of electric meters of the network of FIG. 7 according to some embodiments.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. For example, although the embodiments described herein are in terms of electrical characteristic measurements (for example, voltage and current) it should be understood that the methods described herein may alternatively or additionally be applicable to any type of measurement from any type of sensor of the electric meter. As another example, the systems and methods described herein may also be applicable to output characteristics of the electric meter. As yet another example, some or all of the functionality of the electric utility meter described herein may alternatively or additionally be implemented on a median voltage sensor/substation. As another example, the electrical utility meter may be part of an electrical distribution system for line voltage from a utility grid system, a renewable energy (for example, solar, wind, etc.) grid system, or some combination thereof.

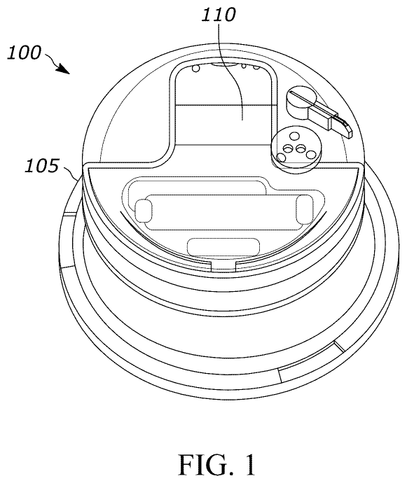

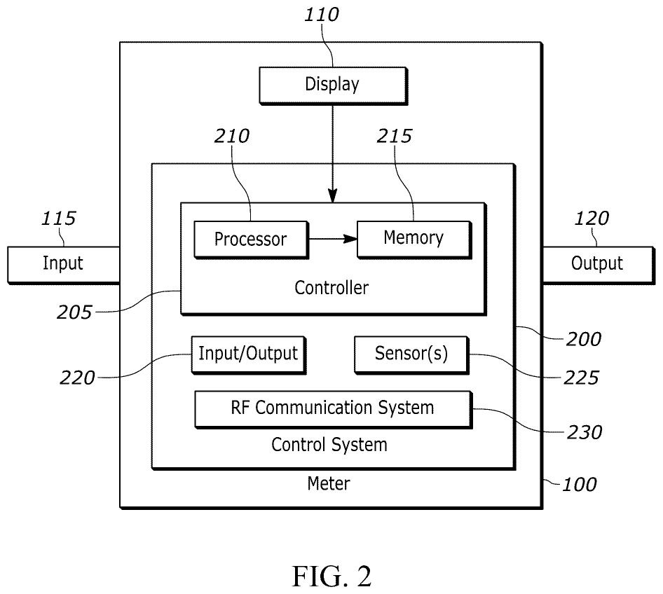

FIG. 1 illustrates an electric utility meter 100 according to some embodiments (referred to herein as electric meter 100). The electric meter 100 may be configured to measure utility consumption (for example, electrical) by a user (for example, a residential user or a commercial user). The electric meter 100 may include a housing 105 and a display 110. The housing 105 may include various electrical and electronic components of the electric meter 100, such as but not limited to, an input 115 (FIG. 2) and an output 120 (FIG. 2). The input 115 is configured to receive electricity, for example, from a utility. The output 120 is configured to output the electricity, for example, for user consumption. The display 110 may be configured to output information to a user. The display 110 may be any suitable display, for example, a liquid crystal display (LCD) touch screen, or an organic light-emitting diode (OLED) touch screen.

FIG. 2 is a block diagram illustrating the electric meter 100 according to some embodiments. In the illustrated embodiment, the electric meter 100 further includes a control system 200 including an electronic controller 205. In some embodiments, the control system 200 is implemented wholly or partially on a printed-circuit board contained within the housing 105.

The controller 205 may have a plurality of electrical and electronic components that provide power, operational control, and protection to the components (for example, but not limited to, an electronic processor 210 and a memory 215). The electronic processor 210 obtains and provides information (for example, from the memory 215), and processes the information by executing one or more software instructions or modules, capable of being stored, for example, in a random access memory (“RAM”) area of the memory 215 or a read only memory (“ROM”) of the memory 215 or another non-transitory computer readable medium (not shown). The software can include firmware, one or more applications, program data, filters, rules, one or more program modules, and other executable instructions. The memory 215 can include one or more non-transitory computer-readable media and includes a program storage area and a data storage area (not shown). The program storage area and the data storage area can include combinations of different types of memory, as described herein. The electronic processor 210 is configured to retrieve from the memory 215 and execute, among other things, software related to the control processes and methods described herein.

The controller 205 may be electrically and/or communicatively connected to a variety of modules and/or components of the electric meter 100. For example, the controller 205 may be electrically and/or communicatively coupled to an input/output (I/O) interface 220 and one or more sensors 225.

The I/O interface 220 may be configured to receive input and/or provide output to one or more external devices. For example, the I/O interface 220 may obtain information and signals from, and provide information and signals to, (for example, over one or more wired and/or wireless connections) external devices. The external devices may include, but are not limited to, one or more servers, an external computer, a smart phone, and/or a tablet. In some embodiments, the I/O interface 220 is, or includes, an advanced metering infrastructure (AMI) module and/or a network interface controller (NIC).

The one or more sensors 225 may be configured to sense one or more characteristics of the meter 100 and/or the input power received from the utility. In some embodiments, the one or more sensors 225 are configured to sense one or more electrical characteristics. In such an embodiment, the one or more electrical characteristics may include a voltage, a current, a power, and/or a temperature. In other embodiments, the one or more sensors 225 are configured to sense acoustical information of the meter 100. In yet other embodiments, the one or more sensors 225 are configured to sense environmental characteristics (for example, ozone) of the meter 100. In yet other embodiments, the one or more sensors 225 are configured to sense radio-frequency information.

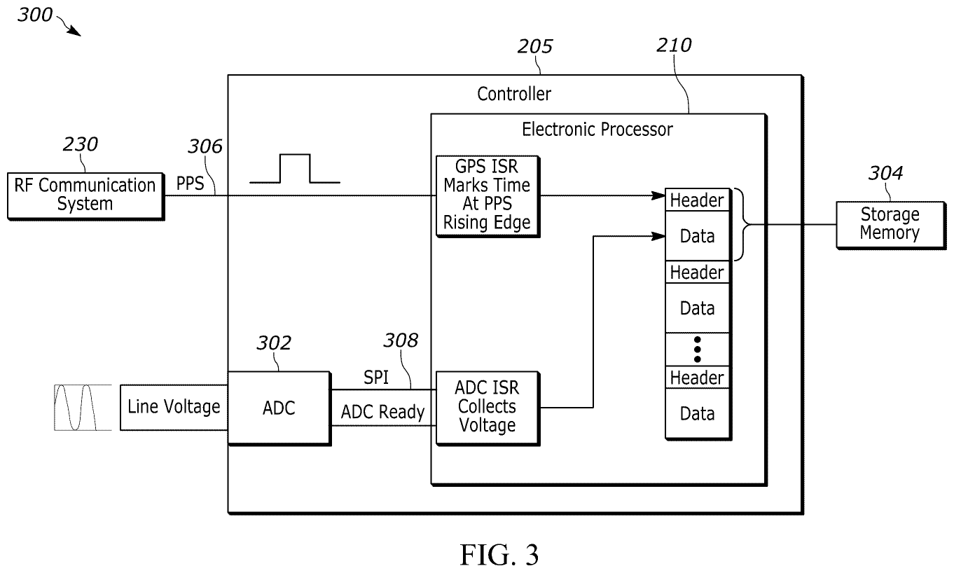

In some embodiments, one or more measurements output from the sensors 225 are provided to the controller 205 (in particular, the electronic processor 210) through an analog to digital converter (ADC) 302 (FIG. 3). In some embodiments, the ADC 302 is a multi-channel converter configured to receive and provide, to the controller 205 more than one measurement signal from more than one sensor 225 at a time. In some embodiments, the controller 205 includes more than one ADC 302.

The radio frequency (RF) communications system 230 is configured to transmit and receive radio communications within one or more frequency bands to and from one or more devices external to the meter 100. The RF communications system 230 may include one or more antennas, tuners, transmitters/receivers, and other various digital and analog components (for example, digital signal processors, high band filters, low band filters, and the like), which for brevity are not described herein. The RF communications system 230 is configured to output a pulse per second (PPS) signal according to a precision clock within the system 230 (which is not shown). A PPS is an electrical signal that has a width of less than one second and a sharply rising or abruptly falling edge that accurately repeats once per second. In some embodiments, the RF communications system 230 is a global positioning system (GPS).

The controller 205, as described above, receives measurement signals from the sensors 225 (for example, through the ADC 302). The clock signal for sampling such measurement signals corresponds to the clock signal of a clock (oscillator) of the controller 205. Such signals may be produced, for example, by a crystal oscillator or clock (not shown). In some embodiments, the clock signal of the controller 205 is approximately 16 or 32 kilo-Hertz (kHz). However, this frequency may change over time, for example, due to environmental conditions (for example, temperature fluctuations, weather conditions, humidity, etc.), aging conditions, or both. Thus, the time associated with a sampled frame of the measurement signal may not be accurate.

One solution is to replace the crystal oscillator of the controller 205 with a new oscillator or other hardware solutions to slow or prevent degradation. However, such solutions may be expensive and time-consuming. Thus, as described herein, the proposed systems and methods are directed to detection and mediation of changes in a sampling frequency of an electric (for example, the meter 100).

FIG. 3 is a schematic circuit diagram of an electrical system 300. The electrical system 300 includes the meter 100 (including the electronic processor 210 and the ADC 302), the RF communications system 230, and a storage memory 304. The storage memory 304 may be configured similar to that of the memory 215 and may be part of an electronic device external to the meter 100 (for example, a remote storage server), integrated into the meter 100 (for example, as part of the memory 215), or some combination thereof. Measurements from the one or more sensors 225 are sampled by the ADC 302, producing the measurement signal 306. Each sample of the measurement signal 306 is stored in the storage memory 304 as a frame (described in more detail below). In addition, the RF communications system 230 provides a PPS signal 308 to the electronic processor 210.

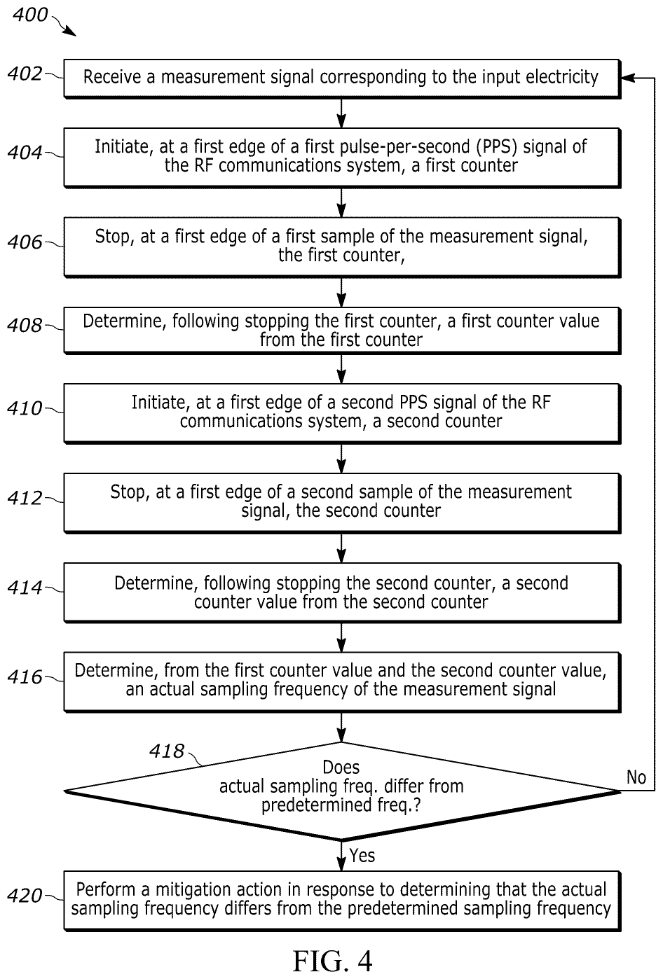

FIG. 4 is a flowchart illustrating a method 400 of detecting and mediating a difference in a sampling frequency of a measurement signal of an electric (for example, the electric meter 100) in accordance with some embodiments. The method 400 is described with respect to the electric meter 100 and as being performed by the controller 205 (in particular, the electronic processor 210). In addition, the method 400 may be modified or performed differently than the specific example provided.

The method 400 begins by the controller 205 receiving (block 402) a measurement signal corresponding to an input electricity (for example, received at the input 115). The measurement signal corresponds to a characteristic of a line voltage from a utility. For example, with reference to FIG. 3, the measurement signal is received from the ADC 302. The measurement signal may correspond to an electrical characteristic of the line voltage (for example, a voltage, a current, and the like). In some embodiments, the measurement signal is used to derive a synchrophasor measurement for a phasor monitoring function performed by the electric meter 100.

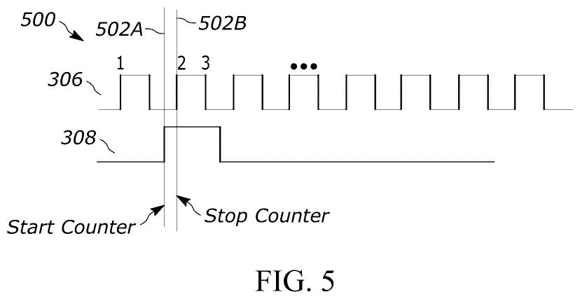

At block 404, the controller 205 initiates a first counter upon detection of a first edge of a first PPS signal 308 of the RF communications system 230. At block 406, the controller 205 stops the first counter in response to detecting a first edge of a first frame of the measurement signal. The controller 205 then determines, following stopping the first counter, a first counter value from the first counter. For example, FIG. 5 is a signal over time diagram 500 including the measurement signal 306 and the PPS signal 308 of the RF communications system 230. With reference to block 404, in the illustrated example, a counter is started upon detection of a rising edge 502A of the PPS signal 308. Upon detection of a rising edge 502B of the measurement signal 306, the counter is stopped (corresponding to block 406 of the method 400 of FIG. 4). The counter value of the counter thus corresponds to an amount of time between the rising edge of the PPS signal 308 and a rising edge of the measurement signal 306. In some embodiments, the counter alternatively is initiated on a falling edge of the PPS signal 308. In further embodiments, the counter is alternatively stopped on a falling edge of the measurement signal 306.

Returning to FIG. 4, at block 410 the controller 205 initiates a second counter at a first edge of a second PPS signal 308 of the RF communication system 230 and, at block 412, stops the second counter at a first edge of a second sample of the measurement signal 306. At block 414, the controller 205 determines a second counter value of the second counter following block 412. The initiation, stopping, and determination of a counter value of the second counter performed in blocks 410, 412, and 414 may be performed similar to that as described above with respect to blocks 404, 406, and 408. In some embodiments, the first sample related to the first counter value is part of a first frame (and, thus, a first PPS pulse of the PPS signal) and the second sample related to the second counter value is part of a second frame (and, thus, a second PPS pulse of the PPS signal). The second frame may be another (but not necessarily the next) frame following the first frame (for example, a 60^{th} frame following the first frame). In some embodiments, both the first PPS and the second PPS signals occur within a single frame.

In some embodiments, the frequency of the first and second counters are approximately 3.9 kHz. The first and second counters, in some embodiments, share the same clock as the measurement signal 306.

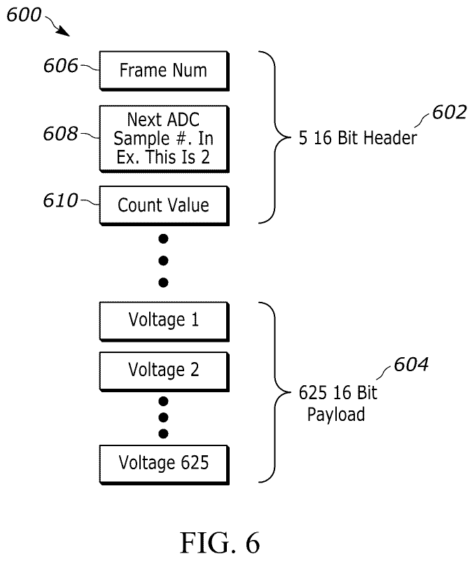

At block 416, the controller 205 determines an actual sampling frequency of the measurement signal 306 from the first counter value and the second counter value. For example, FIG. 6 is a frame structure 600 generated and stored by the controller 205 in accordance with some embodiments. In the illustrated example, the frame structure 600 includes 630 16 bit values. Of the 630 values, 5 are reserved as a frame header 602 and the remaining 625 are reserved as payload 604 (i.e. measurement values, each value being derived from a respective sample of the measurement signal 306). The frame header 602 includes a frame number 606, PPS timing reference 608, and counter value(s) 610. The frame number 606 is a unique value for identifying the particular frame. The PPS timing reference 608 is information indicative of the particular sample that the counter was stopped at (blocks 406 and 412 of the method 400 of FIG. 4). For example, with reference to diagram 500 of FIG. 5, the PPS timing reference 608 would be “Sample 2.” The counter value 610 includes information regarding the counter value (for example, the counter values determined at blocks 408 and 414 of the method 400 of FIG. 4) for a particular pulse of the PPS signal.

For both the first and second samples, a location of the respective PPS pulse in time with reference to the measurement signal is determined based on the respective counter values and the PPS timing reference 608. In determining the location of the respective PPS pulse in time with reference to the measurement signal, the electronic controller 205 may further be configured to determine a real time stamp of each PPS signal. The real time stamp of the PPS signal is a global or local time (for example, determined from local clock information from the electrical meter 100 or from global clock information from the RF communications system 230) additionally determined and stored upon detection of the first edge of the respective PPS pulse. Upon determining the location of each PPS pulse in time with respect to the measurement signal, a number of samples between the first PPS pulse and the second PPS pulse is determined. The actual sampling frequency is then determined by dividing the determined number of samples over the time between the first and second PPS pulses.

Returning to FIG. 4, at block 418 the controller 205 determines whether the determined actual sampling frequency differs from a predetermined sampling frequency. The predetermined sampling frequency may correspond to a frequency in which the measurement signal is expected to be (for example, as described above, 16 or 32 kHz). In instances where the controller 205 determines that the actual sampling frequency does not differ from the predetermined sampling frequency, the controller 205 returns to block 402 of the method 400. In instances where the controller 205 determines that the determined actual sampling frequency does differ from the predetermined sampling frequency, the controller 205 performs a mitigation action (block 420).

In some embodiments, the mitigation action includes adjusting an operation of the electric meter 100. For example, the electric meter 100 may generate a warning indicative that the actual sampling frequency differs from the predetermined sampling frequency. The warning may be an audible or visual warning (or a combination thereof) to a user. For example, the controller 205 may generate the warning on the display 110. In some embodiments, the controller 205 transmits the warning to another external electronic communications device (not shown) (for example, a maintenance server, a utility management server, etc.). In some embodiments, the controller 205 is further configured to determine a difference between the actual sampling frequency and the predetermined sampling frequency. The controller 205 may include the determined difference in the warning to a user.

In some embodiments, the mitigation action includes determining the difference between the actual sampling frequency and the predetermined sampling frequency and performing a re-sampling of the measurement signal according to a selected sampling frequency based on the difference. The controller 205 may re-sample the measurement signal stored in the storage memory 304 by adjusting the stored samples of the measurement signal and sampling the adjusted samples according to a selected sampling frequency (for example, the predetermined or expected sampling frequency). For example, the controller 205 may perform an interpolation of a plurality of sampled frames of the measurement signal, generating a modified measurement signal. The controller 205 may then sample the modified measurement sample according to a selected sampling frequency (for example, the predetermined or expected sampling frequency), producing an adjusted measurement frame. The adjusted measurement frame may then be stored at the storage memory 304 and/or compared to other measurement frames (for example, of the electric meter 100 or of other electric meters within the same electrical network).

Adjustment of measurement frames to a common sampling frequency (i.e. synchronizing sample measurements of frames) may allow for more accurate analysis and comparison of the operational performance of multiple electric meters within an electrical network. Synchronized measurements between meters may be desirable, for example, for determining synchrophasor measurements and/or point on point waveform measurements to detect divergences in phase angle in addition to magnitude. Furthermore, evaluating sampled measurement frames that share a common sampling frequency may allow for more accurate determination as to where in the electrical network (i.e. which phase, at what meter, etc.) a fault may have occurred. Such evaluations may be performed at the electric meter 100, at a remote device (for example, a sever), or some combination thereof.

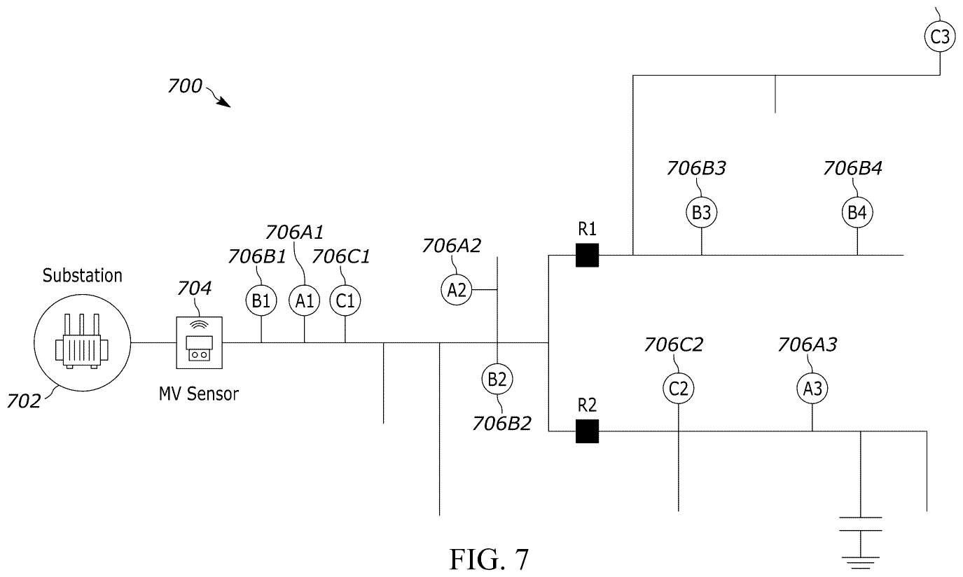

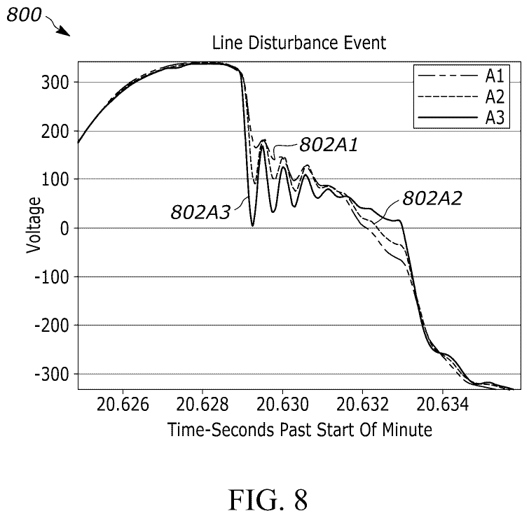

For example, FIG. 7 is an electrical distribution network 700. The network 700 includes a substation 702 configured to provide line voltage to customers of the network 700. In the illustrated example, the substation provides a three-phase line voltage through a median voltage sensor 704 to the rest of the network 700. Downstream from the substation 702 are a plurality of electrical utility meters 706A1-706A3, 706B1-706B4, and 706C1-706C3. The meters 706A1-706A3 measure electrical characteristics of a first phase of the line voltage, the meters 706B1-706B4 measure electrical characteristics of a second phase of the line voltage, and the meters 706C1-706C3 measure electrical characteristics of a third phase of the line voltage. As an example, if a fault occurs in the first phase of the line voltage, measurements of the meters 706A1-706A3 will be affected. FIG. 8 is a diagram 800 of a voltage measurement 802A1-802A3 of each of the meters 706A1-706A3 respectively. Because the voltage measurements from each of the meters 706A1-706A3 are synchronized (whether adjusted via the method 400 of FIG. 4 described above or measured at the expected sampling frequency), the particular location of the fault (in this example, where the fault first occurred) is able to be identified (in the illustrated example, the meter 706A3.

Thus, the disclosure provides, among other things, a system and method for determining and mitigating variations in a sampling frequency of an electric. Various features and advantages of the various embodiments disclosed herein are set forth in the following claims.

What is claimed is:

1. An electric utility meter comprising:
an input configured to receive input electricity from an electricity source;
a radio frequency (RF) communications system; and
a controller having an electronic processor, the electronic processor configured to:
receive a measurement signal corresponding to the input electricity,
initiate, at a first edge of a first pulse-per-second (PPS) signal of the RF communications system, a first counter,
stop, at a first edge of a first sample of the measurement signal, the first counter,
determine, following stopping the first counter, a first counter value from the first counter,
initiate, at a first edge of a second PPS signal of the RF communications system, a second counter,
stop, at a first edge of a second sample of the measurement signal, the second counter,
determine, following stopping the second counter, a second counter value from the second counter,
determine, from the first counter value and the second counter value, an actual sampling frequency of the measurement signal,
compare the actual sampling frequency of the measurement signal to a predetermined sampling frequency, and
perform a mitigation action in response to determining that the actual sampling frequency differs from the predetermined sampling frequency.

2. The electric utility meter of claim 1, wherein the mitigation action includes generating a warning indicative of a difference between the actual sampling frequency and the predetermined sampling frequency.

3. The electric utility meter of claim 1, wherein the mitigation action includes
determining the difference between the actual sampling frequency and the predetermined sampling frequency; and
performing a re-sampling of the measurement signal according to a selected sampling frequency based on the difference.

4. The electric utility meter of claim 3, wherein re-sampling the measurement signal includes performing an interpolation of a plurality of sampled frames of the measurement signal, generating a modified measurement signal and wherein the re-sampling is performed on the modified measurement signal according to a selected sampling frequency.

5. The electric utility meter of claim 1, wherein the predetermined sampling frequency is 16 or 32 kilo-Hertz (kHz).

6. The electric utility meter of claim 1, wherein the measurement signal corresponds to either or both of a voltage and a current.

7. The electric utility meter of claim 1, wherein the RF communications system is a global positioning system (GPS).

8. The electric utility meter of claim 1, wherein the first counter, the second counter, and the measurement signal share a same clock.

9. The electric utility meter of claim 1, wherein the mitigation action includes adjusting an operation of the electric utility meter.

10. An electrical distribution system including an electric utility meter, the electric utility meter including an input configured to receive input electricity from an electricity source, a radio frequency (RF) communications system, and a controller, the controller including an electronic processor, the electronic processor configured to:
receive a measurement signal corresponding to the input electricity,
initiate, at a first edge of a first pulse-per-second (PPS) signal of the RF communications system, a first counter,
stop, at a first edge of a first sample of the measurement signal, the first counter,
determine, following stopping the first counter, a first counter value from the first counter,
initiate, at a first edge of a second PPS signal of the RF communications system, a second counter,
stop, at a first edge of a second sample of the measurement signal, the second counter,
determine, following stopping the second counter, a second counter value from the second counter,
determine, from the first counter value and the second counter value, an actual sampling frequency of the measurement signal,
compare the actual sampling frequency of the measurement signal to a predetermined sampling frequency, and
perform a mitigation action in response to determining that the actual sampling frequency differs from the predetermined sampling frequency.

11. The electrical distribution system of claim 10, wherein the mitigation action includes generating a warning indicative of a difference between the actual sampling frequency and the predetermined sampling frequency.

12. The electrical distribution system of claim 10, wherein the mitigation action includes
determining the difference between the actual sampling frequency and the predetermined sampling frequency; and
performing a re-sampling of the measurement signal according to a selected sampling frequency based on the difference.

13. The electrical distribution system of claim 12, wherein re-sampling the measurement signal includes performing an interpolation of a plurality of sampled frames of the measurement signal, generating a modified measurement signal and wherein the re-sampling is performed on the modified measurement signal according to a selected sampling frequency.

14. The electrical distribution system of claim 10, wherein the predetermined sampling frequency is 16 or 32 kilo-Hertz (kHz).

15. The electrical distribution system of claim 10, wherein the measurement signal corresponds to either or both of a voltage and a current.

16. The electrical distribution system of claim 10, wherein the RF communications system is a global positioning system (GPS).

17. The electrical distribution system of claim 10, wherein the first counter, the second counter, and the measurement signal share a same clock.

18. The electrical distribution system of claim 10, wherein the mitigation action includes adjusting an operation of the electric utility meter.

19. A method of operating an electric utility meter, the method comprising:
receiving, at an input of the electric utility meter, a measurement signal corresponding to an input electricity from an electrical source;
initiating, at a first edge of a first pulse-per-second (PPS) signal of an RF communications system, a first counter;
stopping, at a first edge of a first sample of the measurement signal, the first counter;
determining, following stopping the first counter, a first counter value from the first counter;
initiating, at a first edge of a second PPS signal of the RF communications system, a second counter;
stopping, at a first edge of a second sample of the measurement signal, the second counter;
determining, following stopping the second counter, a second counter value from the second counter;
determining, from the first counter value and the second counter value, an actual sampling frequency of the measurement signal;
comparing the actual sampling frequency of the measurement signal to a predetermined sampling frequency; and
performing a mitigation action in response to determining that the actual sampling frequency differs from the predetermined sampling frequency.

20. The method of claim 19, wherein the mitigation action includes
determining the difference between the actual sampling frequency and the predetermined sampling frequency; and
performing a re-sampling of the measurement signal according to a selected sampling frequency based on the difference.
